(19) United States
(12) Patent Application Publication
(10) Pub. No.: US 2010/0123139 A1
(43) Pub. Date: May 20, 2010

(54) SEMICONDUCTOR WAFER, SEMICONDUCTOR DEVICE, SEMICONDUCTOR WAFER MANUFACTURING METHOD AND SEMICONDUCTOR DEVICE MANUFACTURING METHOD

(75) Inventor: Ken Sato, Niiza-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Sanken Electric Co., Ltd., Niiza-shi (JP)

(21) Appl. No.: 12/620,008

(22) Filed: Nov. 17, 2009

(30) Foreign Application Priority Data
Nov. 20, 2008 (JP) 2008-297068

(51) Int. Cl. H01L 29/205; H01L 21/20

(52) U.S. Cl. 257/76; 438/478; 257/183; 257/615; 257/E21.09; 257/E29.091

(57) ABSTRACT

An aspect of the present invention inheres in a semiconductor wafer includes a support substrate, a first nitride semiconductor layer, at least an upper surface of which has become monocrystalline, the first semiconductor layer being provided on the support substrate, and a second nitride semiconductor layer containing nitrogen and gallium, the second nitride semiconductor layer being provided on the upper surface of the first nitride semiconductor layer.

### CROSS REFERENCE TO RELATED APPLICATIONS

This application is based upon and clams the benefit of priority from the prior Japanese Patent Application No. P2008-297068, filed on Nov. 20, 2008; the entire contents of which are incorporated herein by reference.

### BACKGROUND OF THE INVENTION

1. Field of the Invention

The present invention relates to a semiconductor wafer and a semiconductor device, and particularly relates to a semiconductor wafer and a semiconductor device, each of which has a semiconductor layer of a nitride semiconductor on a support substrate, to a manufacturing method of the semiconductor wafer, and to a manufacturing method of the semiconductor device.

2. Description of the Related Art

As a material of a power element (a high electron mobility transistor (HEMT), a shot key barrier diode or the like), alight emitting diode (LED) or the like, it is common to use a nitride compound semiconductor such as gallium nitride (GaN), indium gallium nitride (InGaN) and aluminum gallium nitride (AlGaN). For the nitride compound semiconductor, used as a base is a substrate, such as a silicon (Si) substrate, a silicon carbide (SiC) substrate and a sapphire substrate, which is made of a material different in type from the nitride compound semiconductor, and the nitride compound semiconductor can be obtained by, for example, a vapor epitaxial growth method such as a metal-organic vapor phase epitaxy (MOVPE) method, molecular beam epitaxy (MBE) method and a hydride vapor phase epitaxy (HVPE) method.

However, there are large differences in lattice constant and thermal expansion coefficient between a semiconductor layer of the nitride semiconductor, such as GaN, which is formed by the epitaxial growth or the like, and a support substrate, such as the silicon substrate and the silicon carbide substrate, which serves as the base thereof. Therefore, with regard to the semiconductor layer provided on the support substrate, a crack has occurred in such an epitaxial growth layer owing to a stress or the like generated based on the differences in lattice constant and thermal expansion coefficient, whereby it has been difficult to form an epitaxial growth layer in which crystallinity and flatness are high.

Accordingly, a proposal has been made, which is of a semiconductor device in which a crystal orientation of the support substrate is taken over to the semiconductor layer to thereby align a crystal orientation of the semiconductor layer in such a manner that a buffer layer having a lattice constant intermediate between that of the support substrate made of silicon and that of the semiconductor layer made of the nitride semiconductor is arranged between the support substrate and the semiconductor layer (for example, refer to the pamphlet of International Publication No. 2004/066393).

However, in the above-described semiconductor device, it cannot still be said that the crystallinity and flatness of the semiconductor layer thereof are fully satisfactory.

### SUMMARY OF THE INVENTION

An aspect of the present invention inheres in a semiconductor wafer includes a support substrate, a first nitride semiconductor layer, at least an upper surface of which has become monocrystalline, the first semiconductor layer being provided on the support substrate, and a second nitride semiconductor layer containing nitrogen and gallium, the second nitride semiconductor layer being provided on the upper surface of the first nitride semiconductor layer.

Another aspect of the invention inheres in a semiconductor device includes a support substrate, a first nitride semiconductor layer, at least an upper surface of which has become monocrystalline, the first semiconductor layer being provided on the support substrate, a second nitride semiconductor layer containing nitrogen and gallium, the second nitride semiconductor layer being provided on the upper surface of the first nitride semiconductor layer, and a plurality of electrodes which apply an electric field to the second nitride semiconductor layer.

Another aspect of the invention inheres in a semiconductor wafer manufacturing method includes growing a first nitride semiconductor layer, at least an upper surface of which has become monocrystalline, on a support substrate, and growing a second nitride semiconductor layer containing nitrogen and gallium on the upper surface of the first nitride semiconductor layer.

Another aspect of the invention inheres in a semiconductor device manufacturing method includes growing a first nitride semiconductor layer, at least an upper surface of which has become monocrystalline, on a support substrate, growing a second nitride semiconductor layer containing nitrogen and gallium on the upper surface of the first nitride semiconductor layer, and forming, on the second nitride semiconductor layer, a plurality of electrodes which apply an electric field to the second nitride semiconductor layer.

### BRIEF DESCRIPTION OF THE DRAWINGS

FIG. 1 is a schematic cross-sectional view of a semiconductor wafer according to an embodiment of the present invention.

FIG. 2 is a schematic plan view of the semiconductor wafer according to the embodiment of the present invention.

FIG. 3 is a schematic cross-sectional view of a high electron mobility transistor of a first example as a semiconductor device according to the embodiment of the present invention.

FIG. 4 is a schematic cross-sectional view of a high electron mobility transistor of a second example as a semiconductor device according to the embodiment of the present invention.

FIG. 5 is a schematic cross-sectional view of a high electron mobility transistor of a third example as a semiconductor device according to the embodiment of the present invention.

FIG. 6 is an enlarged view of a buffer layer of the third example as the semiconductor device according to the embodiment of the present invention.

FIG. 7 is a schematic cross-sectional view of a semiconductor light emitting element of a fourth example as a semiconductor device according to the embodiment of the present invention.

### DETAILED DESCRIPTION OF EXEMPLARY EMBODIMENTS OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set forth such as specific signal values, etc. to provide a thorough understanding of the present invention. However, it will be obvious to those skilled in the art that the present invention may be practiced without such specific details.

### (Semiconductor Wafer)

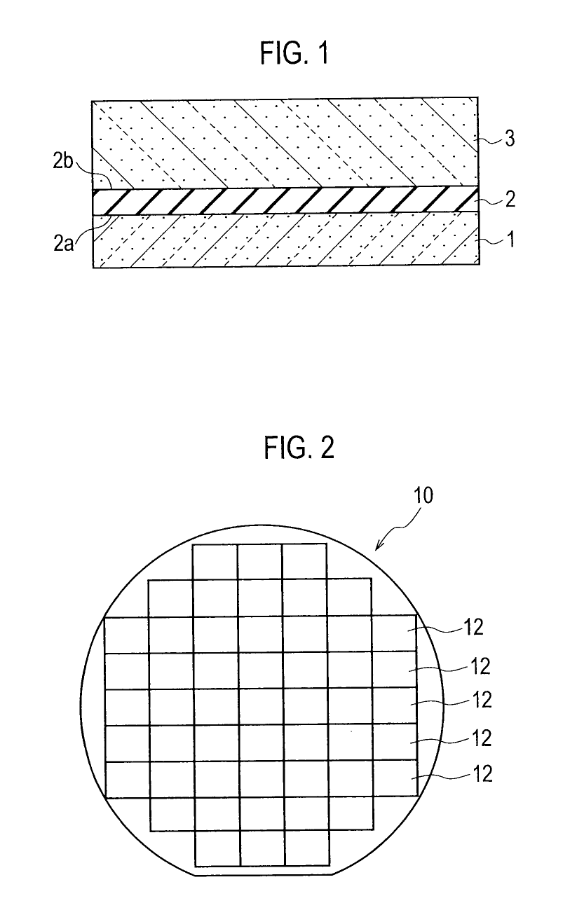

As shown in FIG. 1, a semiconductor wafer according to an embodiment of the present invention includes: a support substrate 1; a first nitride semiconductor layer 2 provided on the support substrate 1, in which at least a surface (lower surface) 2a in contact with the support substrate 1 and a surface (upper surface) 2b opposite with the surface 2a become monocrystalline; and a second nitride semiconductor layer 3 provided on the upper surface 2b of the first nitride semiconductor layer 2 and containing nitrogen and gallium.

The support substrate 1 has a function as a support substrate that mechanically holds the first nitride semiconductor layer 2 and the second nitride semiconductor layer 3, which are to be formed thereon, in order to epitaxially grow the first and second nitride semiconductor layers 2 and 3. The support substrate 1 is formed of silicon (Si), silicon carbide (SiC) or the like. The support substrate 1 is made of such silicon monocrystals having, for example, a thickness of 350 μm to 1000 μm.

The first nitride semiconductor layer 2 is an aluminum (Al)-containing nitride compound semiconductor, such as aluminum nitride (AlN) and aluminum gallium nitride (AlGaN), which has a lattice constant between those of the support substrate 1 and the second nitride semiconductor layer 3. In the first nitride semiconductor layer 2, at least the upper surface 2b thereof becomes monocrystalline. Here, it is desirable that the upper surface 2b of the first nitride semiconductor layer 2 be formed so as to have higher crystallinity than the lower surface 2a of the first nitride semiconductor layer 2, that the lower surface 2a of the first nitride semiconductor layer 2 be formed so as to have low crystallinity, for example, in a polycrystalline form, and that the entire crystallinity of the first nitride semiconductor layer 2 be increased from the lower surface 2a of the first nitride semiconductor layer 2 toward the upper surface 2b of the first nitride semiconductor layer 2. The first nitride semiconductor layer 2 is nitride, in which the lattice constant is approximate to a lattice constant of the support substrate 1, and is smaller than a lattice constant of the second nitride semiconductor layer 3. Accordingly, the first nitride semiconductor layer 2 can take over a crystal orientation of the support substrate 1 to the second nitride semiconductor layer 3, and can evenly align a crystal orientation of the second nitride semiconductor layer 3. The first nitride semiconductor layer 2 is not limited to the above-described case where only the surface 2a in contact with the support substrate 1 and the surface 2b opposite with the surface 2a are monocrystalline, and the entirety of the first nitride semiconductor layer 2 may be monocrystalline. The first nitride semiconductor layer 2 is formed to have a thickness of 10 nm to 600 nm in order to stably form the second nitride semiconductor layer 3.

Moreover, the first nitride semiconductor layer 2 is provided on the entire surface of the support substrate 1 in order to prevent meltback etching caused by the fact that silicon and gallium (Ga) react with each other in the case of adopting a silicon substrate as the support substrate 1. The meltback etching is a so strong etching reaction as to break the surface of the support substrate 1 as a result of the reaction between the support substrate 1 as the silicon substrate and gallium (Ga).

The second nitride semiconductor layer 3 is formed of gallium nitride (GaN), indium gallium nitride (InGaN), aluminum gallium nitride (AlGaN), aluminum indium gallium nitride (AlInGaN) or the like. Specifically, the second nitride semiconductor layer 3 is made of a nitride semiconductor containing nitrogen and any of aluminum, indium, gallium, boron and the like, and functions as an element forming area. For example, the second nitride semiconductor layer 3 can be formed into a light emitting element structure as a double heterostructure having a light emitting area, or into an electronic device structure as a hetero structure, for example, of an HEMT.

A description will be made below of a manufacturing method of a semiconductor wafer 10 according to the embodiment of the present invention.

(A) First, the support substrate 1 composed of the silicon substrate of silicon, silicon carbide or the like is prepared.

(B) Next, an oxide film on a surface of the support substrate 1 is removed, and thereafter, the support substrate 1 is introduced into a processing chamber of an MOCVD apparatus (not shown), and is arranged on a heatable and rotatable susceptor. Note that an atmosphere in the processing chamber is evacuated so that a pressure in the processing chamber can become 1/10 atmospheric pressure to the normal atmospheric pressure. Then, the first nitride semiconductor layer 2 is formed on a (111) plane of the support substrate 1 by being epitaxially grown by using an MOCVD method. Here, at least the upper surface 2b of the first nitride semiconductor layer 2 has become monocrystalline. Note that, in such a forming process of the first nitride semiconductor layer 2, a temperature of the support substrate 1 is initially set at 1000° C., and a temperature gradient is provided therefrom to approximately 1300° C., whereby it becomes possible to adopt a configuration, in which the lower surface 2a side of the first nitride semiconductor layer 2 has low crystallinity, for example, since the lower surface 2a side has a polycrystalline structure, and so on, and the crystallinity is increased from the lower surface 2a of the first nitride semiconductor layer 2 toward the upper surface 2b of the first nitride semiconductor layer 2.

(C) Next, the second nitride semiconductor layer 3 made of, for example, GaN or the like is stacked on the upper surface 2b of the first nitride semiconductor layer 2 that is monocrystalline. In the case of stacking the second nitride semiconductor layer 3 made of GaN, specifically, ammonia gas and trimethylgallium (TMG) gas are supplied into the processing chamber by means of carrier gas, and the second nitride semiconductor layer 3 is stacked by being epitaxially grown.

By the above-described steps, the semiconductor wafer 10 according to the embodiment, which is an epitaxial growth substrate, is provided.

In accordance with the semiconductor wafer according to the embodiment of the present invention, the second nitride semiconductor layer 3 is provided on the upper surface 2b of the first nitride semiconductor layer 2, which has become monocrystalline, whereby quality of the crystals of the second nitride semiconductor layer 3 is put in order, and crystallinity and flatness of the second nitride semiconductor layer 3 can be enhanced.

Moreover, in accordance with the semiconductor wafer according to the embodiment of the present invention, if the lower surface 2a of the first nitride semiconductor layer 2, which is in contact with the support substrate 1, is made of crystals having lower crystallinity than the upper surface 2b, then spots of the crystals having lower crystallinity can relieve a stress, and a warp and a crack, which occur in the second nitride semiconductor layer 3 as the epitaxial growth layer, can be suppressed.

Furthermore, in accordance with the semiconductor wafer according to the embodiment of the present invention, the first nitride semiconductor layer 2 is relatively thick, and the crystallinity of the upper surface 2b thereof is high, whereby diffusion of Ga into the support substrate 1 is prevented, the meltback etching is prevented, and blocking voltage in the vertical direction of the semiconductor wafer is enhanced. In such a way, electronic devices having high blocking voltage can be created.

### (Semiconductor Device)

On the semiconductor wafer 10 according to the embodiment, as shown in FIG. 2, a plurality of semiconductor chips 12 are formed. Each of the semiconductor chips 12 is a chip formed by integrating semiconductor devices which exert a predetermined function. Examples of the semiconductor device formed by using the semiconductor wafer 10 manufactured by the above-described manufacturing method will be shown below.

### First Example

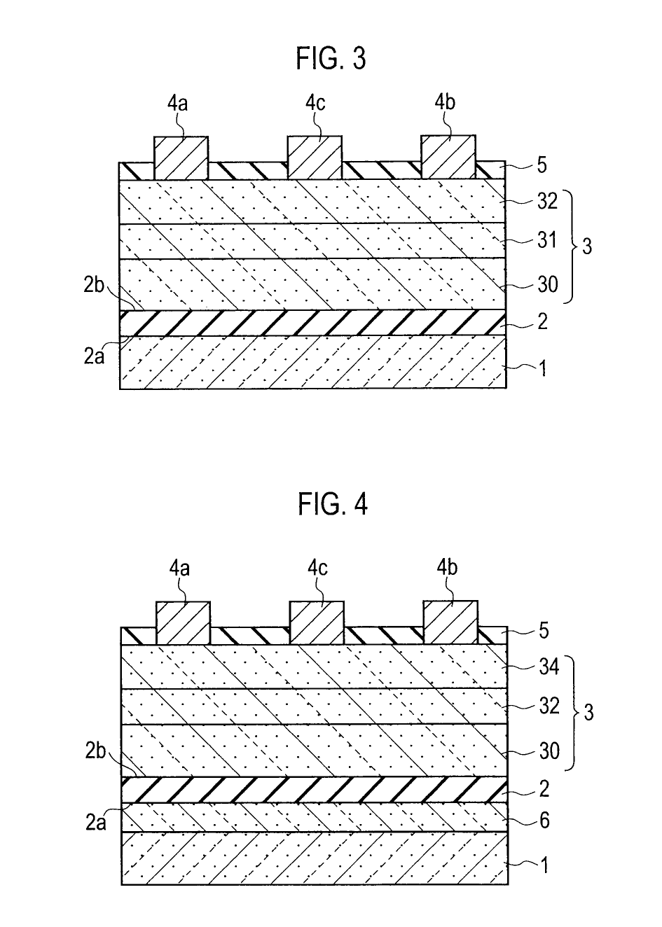

A first example of the semiconductor device according to the embodiment of the present invention is, as shown in FIG. 3, a high electron mobility transistor (HEMT) including: the support substrate 1; the first nitride semiconductor layer 2 provided on the support substrate 1, in which at least the surface (lower surface) 2a in contact with the support substrate 1 and the surface (upper surface) 2b opposite with the surface 2a become monocrystalline; the second nitride semiconductor layer 3 provided on the upper surface 2b of the first nitride semiconductor layer 2 and containing nitrogen and gallium; and a plurality of electrodes 4a, 4b and 4c, which apply an electric field to the second nitride semiconductor layer 3.

The second nitride semiconductor layer 3 has a structure, in which an electron transit layer (channel layer) 30 provided on the upper surface 2b of the first nitride semiconductor layer 2, a spacer layer 31 provided on the electron transit layer 30, and an electron supply layer 32 provided on the spacer layer 31 are stacked on one another. The electron transit layer 30 is, for example, GaN or the like, into which impurities are not doped, and has a thickness of approximately 500 nm. The spacer layer 31 is a functional layer to be provided for the purpose of spatially separating the electron transit layer 30 and the electron supply layer 32 from each other so that two-dimensional electrons in an inside of the electron transit layer 30 cannot be inhibited by dispersion of the ionized impurities. The spacer layer 31 is formed of AlN, AlGaN or the like. Note that it is also possible to adopt a configuration in which this spacer layer 31 is omitted. The electron supply layer 32 is AlGaN or the like, which supplies the electron transit layer 30 with electrons generated from donor impurities (n-type impurities), and the electron supply layer 32 has a thickness of, for example, 30 nm. Band gap energy of the electron supply layer 32 is wider than that of the electron transit layer 30, whereby the electron supply layer 32 generates a two-dimensional electron gas layer in the vicinity of a surface of the electron transit layer 30.

The electrodes 4a, 4b and 4c are provided on the second nitride semiconductor layer 3. The electrode 4a is a source electrode, the electrode 4b is a drain electrode, and the electrode 4c is a gate electrode. The electrodes 4a and 4b make ohmic connections to the two-dimensional electron gas layer, and the electrode 4c has a shot key barrier to the two-dimensional electron gas layer. An insulating film 5 is a silicon oxide (SiO₂) film or the like for insulating spots on a surface of the electron supply layer 32, which exclude those in contact with the electrodes 4a, 4b and 4c.

A description will be made below of a manufacturing method of the semiconductor device according to the first example of the embodiment of the present invention.

(A) First, the support substrate 1 as a silicon substrate made of silicon, silicon carbide or the like is prepared. Next, the oxide film on the surface of the support substrate 1 is removed, and thereafter, the support substrate 1 is introduced into the processing chamber of the MOCVD apparatus (not shown), and is arranged on the heatable and rotatable susceptor. Note that the atmosphere in the processing chamber is evacuated so that the pressure in the processing chamber can become 1/10 atmospheric pressure to the normal atmospheric pressure. Then, the first nitride semiconductor layer 2 composed, for example, of AlN, in which at least the upper surface 2b becomes monocrystalline, is formed on the support substrate 1 by being epitaxially grown by using the MOCVD method. Specifically, ammonia gas and trimethylaluminum (TMA) gas are supplied into the processing chamber by means of the carrier gas, and the first nitride semiconductor layer 2 composed of an AlN layer is grown on the support substrate 1. In the forming process of the first nitride semiconductor layer 2, a temperature of the support substrate 1 is initially set at 1000° C., and a temperature gradient is provided therefrom to approximately 1300° C., whereby it becomes possible to adopt a configuration, in which the lower surface 2a side of the first nitride semiconductor layer 2 has low crystallinity, for example, since the lower surface 2a side has a polycrystalline structure, and so on, and the crystallinity is increased from the lower surface 2a of the first nitride semiconductor layer 2 toward the upper surface 2b of the first nitride semiconductor layer 2.

(B) Next, the electron transit layer 30 composed of a GaN layer into which the impurities are not doped is epitaxially grown on the monocrystalline upper surface 2b of the first nitride semiconductor layer 2. Specifically, the ammonia gas and the TMG gas are supplied into the processing chamber by means of the carrier gas, whereby the electron transit layer 30 composed of the non-doped GaN layer is grown on the upper surface 2b of the first nitride semiconductor layer 2, which has become monocrystalline.

(C) Next, the ammonia gas, the TMG gas and the TMA gas are supplied into the processing chamber by means of the carrier gas, whereby the spacer layer 31 composed of an AlGaN layer into which the impurities are not doped is grown on the electron transit layer 30.

(D) Next, the ammonia gas, the TMG gas, the TMA gas and silane gas are supplied into the processing chamber by means of the carrier gas, whereby the electron supply layer 32 composed of an n-type AlGaN layer into which silicon is doped is epitaxially grown on the spacer layer 31.

(E) Next, the support substrate 1, on which the first nitride semiconductor layer 2, the electron transit layer 30, the spacer layer 31 and the electron supply layer 32 are epitaxially grown, is taken out of the MOCVD apparatus, and the insulating film 5 made of SiO₂ is formed on the entire surface of the electron supply layer 32 by well-known plasma chemical vapor deposition (plasma CVD) or the like.

(F) Next, openings for forming the source electrode and the drain electrode are formed in the insulating film 5 by using a well-known photolithography technology. Thereafter, titanium (Ti) and Al are sequentially stacked and formed on the insulating film 5 by using electron beam evaporation or the like, and unnecessary portions of such an evaporated layer are lifted off. Thereafter, remaining portions of the evaporated layer are annealed, whereby the source electrode 4a and the drain electrode 4b are formed. Also at the time of forming the gate electrode 4c, an opening is formed in the insulating film 5 in a similar procedure, then for example, nickel (Ni) and gold (Au), or palladium (Pd), Ti and Au, are evaporated on the insulating film 5 by the electron beam evaporation, and unnecessary portions of such an evaporated layer are lifted off, whereby the gate electrode 4c having a function as a shot key barrier electrode is formed.

(G) Next, such an epitaxial wafer is cut and separated at element separating portions by a well-know dicing step or the like, whereby an individualized semiconductor device (HEMT) is completed.

In accordance with the semiconductor device according to the first example of the embodiment of the present invention, the electron transit layer 30, the spacer layer 31 and the electron supply layer 32, which compose the second nitride semiconductor layer 3, are provided on the surface 2b of the first nitride semiconductor layer 2, which has become monocrystalline. In such a way, the quality of the crystals of the second nitride semiconductor layer 3 is put in order, and the crystallinity and flatness of the second nitride semiconductor layer 3 can be enhanced. Moreover, in the semiconductor device that requires the blocking voltage in the vertical (thickness) direction, the quality of the crystals of the second nitride semiconductor layer 3 as the epitaxial growth layer is enhanced, whereby the blocking voltage in the vertical direction of the semiconductor device can be enhanced. Furthermore, if the lower surface 2a of the first nitride semiconductor layer 2, which is in contact with the support substrate 1, is made of the crystals having lower crystallinity than the upper surface 2b, then the crystals having lower crystallinity can relieve the stress, and the warp and the crack, which occur in the second nitride semiconductor layer 3, can be suppressed, and the second nitride semiconductor layer 3 can be formed to be thick while maintaining high crystallinity thereof. Moreover, the first nitride semiconductor layer 2 is relatively thick, and the crystallinity of the upper surface 2b thereof is enhanced, whereby the diffusion of Ga into the support substrate 1 is prevented, the meltback etching is prevented, and the blocking voltage of the semiconductor device, which is high in the vertical direction, can be obtained.

### Second Example

As shown in FIG. 4, a second example of the semiconductor device according to the embodiment of the present invention is different from the semiconductor device as the first example, which is shown in FIG. 3, in that an intermediate layer 6, at least a part of which is polycrystalline, is further provided between the support substrate 1 and the first nitride semiconductor layer 2. Others are substantially similar to those of the semiconductor device shown in FIG. 3, and accordingly, a duplicate description will be omitted.

Since the intermediate layer 6 is polycrystalline, the first nitride semiconductor layer 2 provided on the intermediate layer 6 is formed on the intermediate layer 6 through processes of new nucleation and two-dimensional growth. Hence, the first nitride semiconductor layer 2 can be formed without receiving interference from the support substrate 1 because of the presence of the intermediate layer 6. Accordingly, the problems caused by the difference in crystal orientation and the like between the support substrate 1 and the first nitride semiconductor layer 2 are avoided.

With regard to a forming method of the intermediate layer 6, for example, the ammonia gas, the TMG gas and the TMA gas are supplied into the processing chamber by means of the carrier gas, whereby the intermediate layer 6 composed of an AlGaN layer is grown and thereby formed on the support substrate 1.

In accordance with the second example of the embodiment of the present invention, the second nitride semiconductor layer 3 is provided on the surface 2b of the first nitride semiconductor layer 2, which has become monocrystalline. Accordingly, the quality of the crystals of the second nitride semiconductor layer 3 is put in order, and the crystallinity and flatness of the second nitride semiconductor layer 3 can be enhanced.

Moreover, in accordance with the semiconductor device according to the second example, the intermediate layer 6 is provided between the support substrate 1 and the first nitride semiconductor layer 2, whereby the problems caused by the difference in crystal orientation and the like between the support substrate 1 and the second nitride semiconductor layer 3 are further suppressed. Accordingly, the crystallinity and flatness of the second nitride semiconductor layer 3 can be further enhanced.

### Third Example

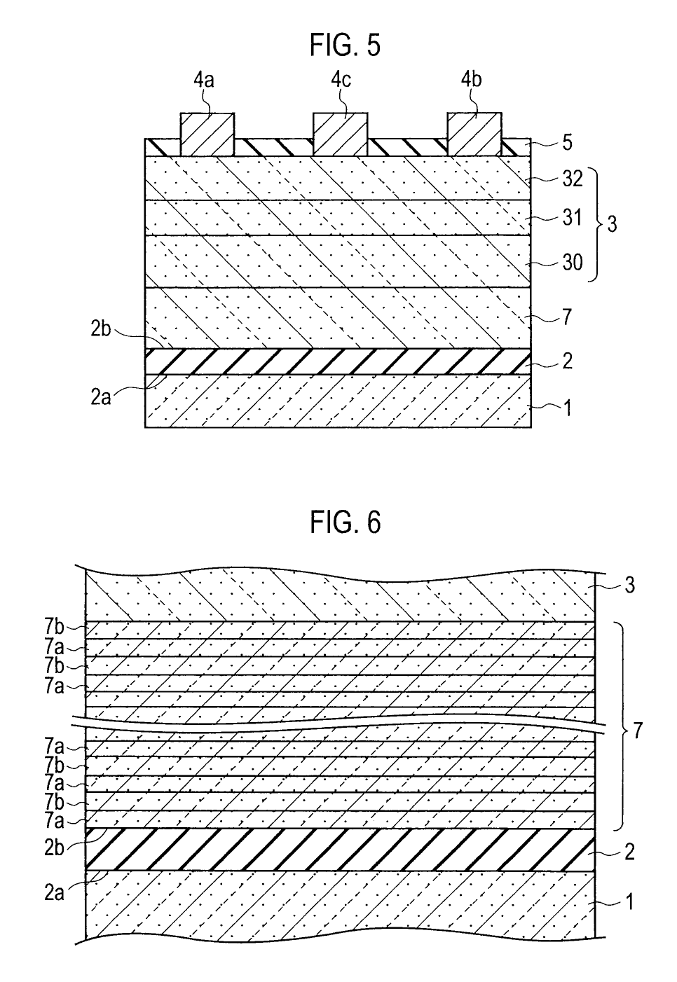

As shown in FIG. 5, a third example of the semiconductor device according to the embodiment of the present invention is different from the semiconductor device as the first example, which is shown in FIG. 3, in that a buffer layer 7 is further provided on the surface 2b of the first nitride semiconductor layer 2, which has become monocrystalline. Others are substantially similar to those of the semiconductor device shown in FIG. 3, and accordingly, a duplicate description will be omitted.

The buffer layer 7 is a cushioning layer for adjusting interaction intensity between the support substrate 1 and the second nitride semiconductor layer 3 to be grown thereon. For example, the buffer layer 7 can be formed into a buffer layer in which a composition of Al in the AlGaN layer is gradually reduced upward, and into a multiple buffer layer in which first buffer layers 7a formed of GaN and second buffer layers 7b formed of AlN are repeatedly formed on one another as shown in FIG. 6.

With regard to a forming method of the buffer layer 7, the first buffer layer 7a is formed on the upper surface 2b of the first nitride semiconductor layer 2 by a vapor epitaxial growth method such as the MOCVD. Here, in the first nitride semiconductor layer 2, at least the upper surface 2b has become monocrystalline. Specifically, the ammonia gas and the TMG gas are supplied into the processing chamber by means of the carrier gas, whereby the first buffer layer 7a composed of the non-doped GaN layer is grown on the surface 2b of the first nitride semiconductor layer 2, which has become monocrystalline. Then, the second buffer layer 7b is formed on the first buffer layer 7a by the vapor epitaxial growth method such as the MOCVD method. Specifically, the ammonia gas and the TMA gas are supplied into the processing chamber by means of the carrier gas, whereby the second buffer layer 7b composed of the AlN layer is grown on the first buffer layer 7a. Moreover, the first buffer layers 7a and the second buffer layers 7b are sequentially stacked on one another, whereby the multiple buffer layer (buffer layer) 7 is formed. The number of pairs of the first buffer layers 7a and second buffer layers 7b in the multiple buffer layer 7 can be decided as appropriate. However, in both of the cases where the number of pairs is too small and too large, the crystallinity is deteriorated, and accordingly, it is preferable that the number of pairs approximately range from 2 to 100. Moreover, in order to reduce a resistance value of at least either of the first buffer layers 7a and the second buffer layers 7b, impurities such as Si may be added to at least either of the first buffer layers 7a and the second buffer layers 7b.

In accordance with the third example of the embodiment of the present invention, the buffer layer 7 is provided on the surface 2b of the first nitride semiconductor layer 2, which has become monocrystalline. Accordingly, quality of crystals of the buffer layer 7 is put in order, and the crystallinity and flatness of the buffer layer 7 are enhanced. Moreover, the second nitride semiconductor layer 3 provided on the buffer layer 7 grows based on the crystallinity and flatness of the buffer layer 7, and accordingly, the crystallinity and flatness of the second nitride semiconductor layer 3 can also be enhanced.

Moreover, in accordance with the semiconductor device according to the third example, the buffer layer 7 is provided between the support substrate 1 and the first nitride semiconductor layer 2, whereby the buffer layer 7 adjusts the interaction intensity between the support substrate 1 and the second nitride semiconductor layer 3 to be grown thereon. Accordingly, the crystallinity and flatness of the second nitride semiconductor layer 3 can be further enhanced.

### Fourth Example

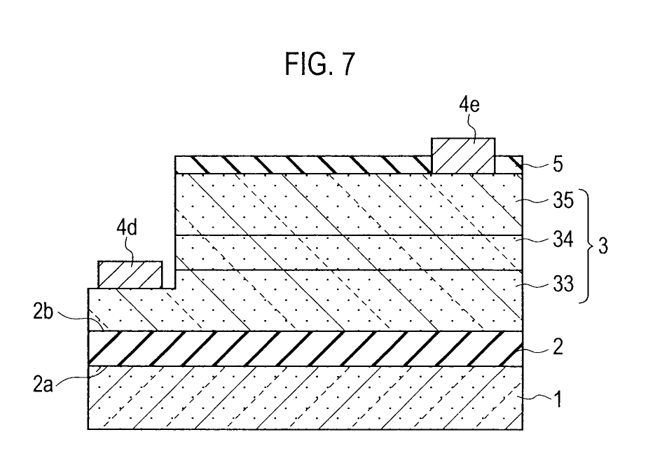

As shown in FIG. 7, a fourth example of the semiconductor device according to the embodiment of the present invention is a semiconductor light emitting element including: the support substrate 1; the first nitride semiconductor layer 2 in which at least the upper surface 2b has become monocrystalline; the second nitride semiconductor layer 3 provided on the upper surface 2b of the first nitride semiconductor layer 2 and containing nitrogen and gallium; and a plurality of electrodes 4e and 4d which apply an electric field to the second nitride semiconductor layer 3.

The second nitride semiconductor layer 3 has a structure, in which a first semiconductor layer (n-type cladding layer) 33 provided on the surface 2b of the first nitride semiconductor layer 2, which has become monocrystalline, an active layer 34 provided on the first semiconductor layer 33, and a second semiconductor layer (p-type cladding layer) 35 provided on the active layer 34, are stacked on one another. The first semiconductor layer 33 is an n-type GaN layer or the like, into which silicon is doped as an n-type dopant, and has a thickness of approximately 3 μm. The active layer 34 can adopt a multiple quantum well structure (MWQ) in which silicon-doped InGaN layers and silicon-doped GaN layers are stacked alternately in approximately five cycles. Note that the quantum well structure of the active layer 34 does not have to be multiplexed, and the number of well layers therein may be one, and the quantum well structure can be formed into a single quantum well structure (SQW). The second semiconductor layer 35 is a p-type GaN layer or the like, into which magnesium is doped as a p-type dopant, and has a thickness of approximately 70 nm.

The active layer 34 is supplied individually with carriers of a first conductivity type from the first semiconductor layer 33, and with carriers with a second conductivity type from the second semiconductor layer 35. In the case where the first conductivity type is the n type, and the second conductivity type is the p type, electrons supplied from the first conductive layer 33 and holes supplied from the second semiconductor layer 35 are recombined with each other in the active layer 34, and light is emitted from the active layer 34.

The electrode 4d is a cathode electrode that applies a voltage to the first semiconductor layer 33, and the electrode 4e is an anode electrode that applies a voltage to the second semiconductor layer 35. An insulating film 5 is a silicon oxide film or the like for insulating spots on a surface of the second semiconductor layer 35, which exclude that in contact with the electrode 4e.

A description will be made below of a manufacturing method of the semiconductor device according to the fourth example of the embodiment of the preset invention.

(A) First, the support substrate 1 as a silicon substrate made of silicon, silicon carbide or the like is prepared. Next, an oxide film on the surface of the support substrate 1 is removed, and thereafter, the support substrate 1 is introduced into the processing chamber of the MOCVD apparatus (not shown), and is arranged on the heatable and rotatable susceptor. Note that the atmosphere in the processing chamber is evacuated so that the pressure in the processing chamber can become 1/10 atmospheric pressure to the normal atmospheric pressure. Then, the first nitride semiconductor layer 2 composed, for example, of AlN is formed on the support substrate 1 by being epitaxially grown by using the MOCVD method. Specifically, the ammonia gas and the TMA gas are supplied into the processing chamber by means of the carrier gas, and the first nitride semiconductor layer 2 composed of the AlN layer, in which at lest the upper surface 2b is monocrystalline, is grown on the support substrate 1. In the forming process of the first nitride semiconductor layer 2, the temperature of the support substrate 1 is initially set at 1000° C., and the temperature gradient is provided therefrom to approximately 1300° C., whereby it becomes possible to adopt a configuration, in which the lower surface 2a side of the first nitride semiconductor layer 2 has low crystallinity, for example, since the lower surface 2a side has a polycrystalline structure, and so on, and the crystallinity is increased from the lower surface 2a of the first nitride semiconductor layer 2 toward the upper surface 2b of the first nitride semiconductor layer 2.

(B) Next, the first semiconductor layer 33 composed of the n-type GaN layer is epitaxially grown on the monocrystalline surface 2b of the first nitride semiconductor layer 2, which is opposite with the surface 2a in contact with the support substrate 1. Specifically, the ammonia gas, the trimethylgallium gas and the silane gas are supplied into the processing chamber by means of the carrier gas, whereby the first semiconductor layer 33 composed of the n-type GaN layer into which silicon is doped is grown.

(C) Next, the ammonia gas and the trimethylgallium gas are supplied into the processing chamber by means of the carrier gas, whereby a non-doped GaN layer is grown, and thereafter, the silane gas and trimethylindium gas are supplied thereinto together with the above-described gases, whereby an InGaN layer into which silicon is doped is grown. Then, a step of growing the non-doped GaN layer and a step of growing the InGaN layer into which silicon is doped are repeated alternately a desired number of times, whereby the active layer 34 having the quantum well structure is formed. Thereafter, the ammonia gas and the trimethylgallium gas are supplied into the processing chamber by means of the carrier gas, whereby a final barrier layer (not shown) composed of a GaN layer is grown on the active layer 34.

(D) Next, the ammonia gas, the trimethylgallium gas, the trimethylaluminum gas and ethylcyclopentadienyl magnesium gas are supplied into the processing chamber by means of the carrier gas, whereby a p-type electron stopping layer (not shown) composed of a p-type AlGaN layer into which magnesium is doped is grown on the final barrier layer.

(E) Next, the ammonia gas, the trimethylgallium gas and the ethylcyclopentadienyl magnesium gas are supplied into the processing chamber by means of the carrier gas, whereby the p-type second semiconductor layer 35 composed of a GaN layer into which magnesium is doped is grown. In such a way, the semiconductor layer (light emitting portion) 3 is completed.

(F) Next, the electrode 4e made of ZnO is formed on an upper surface of the second semiconductor layer 35 by a sputtering method or a vacuum evaporation method.

(G) Next, a resist is formed into a desired pattern, and the electrode 4e and the second nitride semiconductor layer 3 is etched, whereby a partial area of the first semiconductor layer 33 is mesa-etched, and an electrode surface is exposed. Then, on the exposed electrode surface, a Ti layer and an Al layer are sequentially stacked by a resistance heating method or the vacuum evaporation method such as an electron beam method, whereby the electrode 4d is formed.

(H) Next, the epitaxial wafer is cut and separated at element separating portions by the well-know dicing step or the like, whereby an individualized semiconductor device (light emitting element) is completed.

In accordance with the semiconductor device according to the fourth example of the embodiment of the present invention, the first semiconductor layer 33, the active layer 34 and the second semiconductor layer 35, which compose the second nitride semiconductor layer 3, are provided on the surface 2b of the first nitride semiconductor layer 2, which has become monocrystalline. In such a way, the quality of the crystals of the second nitride semiconductor layer 3 is put in order, and the crystallinity and flatness of the second nitride semiconductor layer 3 can be enhanced.

### Other Embodiment

The description has been made as above of the present invention with reference to the embodiment; however, it should not be understood that the description and the drawings, which compose a part of this disclosure, limit this invention. From this disclosure, various alternative embodiments, examples and operational technologies will become apparent to those skilled in the art.

For example, it is also possible to compose a semiconductor device including both of the intermediate layer 6 shown in the second example and the buffer layer 7 shown in the third example.

Moreover, in the fourth example, the first semiconductor layer 33 is formed into the p-type cladding layer, and the second semiconductor layer 35 is formed into the n-type cladding layer; however, the p-type cladding layer and the n-type cladding layer may be arranged reversely in such a manner that the first semiconductor layer 33 is formed into the n-type cladding layer, and the second semiconductor layer 35 is formed into the p-type cladding layer.

Various modifications will become possible for those skilled in the art after receiving the teachings of the present disclosure without departing from the scope thereof.

What is claimed is:

1. A semiconductor wafer comprising:
a support substrate;
a first nitride semiconductor layer, at least an upper surface of which has become monocrystalline, the first semiconductor layer being provided on the support substrate; and
a second nitride semiconductor layer containing nitrogen and gallium, the second nitride semiconductor layer being provided on the upper surface of the first nitride semiconductor layer.

2. The semiconductor wafer of claim 1,
wherein the support substrate is a silicon substrate, and
the first nitride semiconductor layer is made of a nitride semiconductor containing aluminum, and crystallinity of the first nitride semiconductor layer on the support substrate side is lower than crystallinity of the first nitride semiconductor layer on the second nitride semiconductor side.

3. A semiconductor device comprising:
a support substrate;
a first nitride semiconductor layer, at least an upper surface of which has become monocrystalline, the first semiconductor layer being provided on the support substrate;
a second nitride semiconductor layer containing nitrogen and gallium, the second nitride semiconductor layer being provided on the upper surface of the first nitride semiconductor layer; and
a plurality of electrodes which apply an electric field to the second nitride semiconductor layer.

4. A semiconductor wafer manufacturing method comprising:
growing a first nitride semiconductor layer, at least an upper surface of which has become monocrystalline, on a support substrate; and
growing a second nitride semiconductor layer containing nitrogen and gallium on the upper surface of the first nitride semiconductor layer.

5. A semiconductor device manufacturing method comprising:
growing a first nitride semiconductor layer, at least an upper surface of which has become monocrystalline, on a support substrate;
growing a second nitride semiconductor layer containing nitrogen and gallium on the upper surface of the first nitride semiconductor layer; and
forming, on the second nitride semiconductor layer, a plurality of electrodes which apply an electric field to the second nitride semiconductor layer.
